(19) United States
(12) Patent Application Publication
(10) Pub. No.: US 2018/0305614 A1
(43) Pub. Date: Oct. 25, 2018

(54) PHOTOCONDUCTIVE NANOCOMPOSITE FOR NEAR-INFRARED DETECTION

(71) Applicant: SINGAPORE UNIVERSITY OF TECHNOLOGY AND DESIGN, Singapore (SG)

(72) Inventors: Yi TONG, Singapore (SG); Rong ZHAO, Singapore (SG); Xinyu ZHAO, Singapore (SG); Mei Chee TAN, Singapore (SG)

(21) Appl. No.: 15/771,291

(22) PCT Filed: Oct. 26, 2016
(86) PCT No.: PCT/SG2016/050523

§ 371 Date: Apr. 26, 2018

(30) Foreign Application Priority Data
Oct. 26, 2015 (SG) 10201508815V

(51) Int. Cl. C09K 11/77; C09K 11/02; H01L 51/42

(52) U.S. Cl. CPC C09K 11/7773; H01L 51/4213; C09K 11/02

(57) ABSTRACT

The invention relates generally to photoconductive nanocomposite for near-infrared detection, and in particular, to cost-effective and highly photoresponsive photoconductive nanocomposite for near-infrared detection. In particular, the photoconductive nanocomposite comprises a photoconductive composite film of poly(3-hexyl-thiophene-2,5-diyl) (P3HT) mixed with NaYF4:Yb,Er nanophosphors. A method of forming an optoelectronic device cmprising the photoconductive nanocomposite is also disclosed herein.

### CROSS-REFERENCE TO RELATED APPLICATION

This application claims the benefit of priority of Singapore Patent Application No. 10201508815V, filed Oct. 26, 2015, the contents of which being hereby incorporated by reference in its entirety for all purposes.

### TECHNICAL FIELD

The invention relates generally to photoconductive nanocomposite for near-infrared detection, and in particular, to cost-effective and highly photoresponsive photoconductive nanocomposite for near-infrared detection. In particular, the photoconductive nanocomposite comprises a photoconductive composite film of poly(3-hexylthiophene-2,5-diyl) (P3HT) mixed with NaYF₄:Yb,Er nanophosphors. A method of forming an optoelectronic device comprising the photoconductive nanocomposite is also disclosed herein.

### BACKGROUND

Continuous efforts have been invested to enhance the conversion of light to electrical signals motivated by the diverse range of emerging technological applications, such as photodetectors, optical communications, sensors, photonic memory, photocatalysts, solar cells, spectroscopy, and phototransistors. Within the full electromagnetic spectrum, near-infrared (NIR) light has recently garnered rising attention due to the emerging applications in night-vision imaging, biomedical imaging, security, and solar energy conversion. To convert photons to electrical signals, most of the traditional materials used are semiconductor materials with direct- or indirect-bandgap, such as silicon, germanium, and III-V materials. Since these semiconductors only absorb photons with energy higher than the semiconductor bandgap, they typically exhibit a weak absorbance in the near-infrared regime. Even though III-V semiconductors can be fine-tuned to absorb more near-infrared light, the cost of III-V materials is high due to the complex and costly physical deposition and epitaxial growth methods. Therefore, a material system that can be made using cost-effective and versatile processing technologies with a high efficiency of conversion of near-infrared light to electrical signals needs to be developed urgently.

In addition, the next generation of electronics demands the development of flexible devices (e.g. devices of organic materials) to supersede the conventional semiconductor devices without losing any functions. Although organic semiconductors are used to improve the flexibility of devices, the relatively large bandgap of these organic semiconductors limit the absorption of near-infrared light. Despite the efforts that have been invested made towards improving the response of organic semiconductor, such as P3HT to NIR light, high photoresponse with P3HT was not achieved. To improve the response of organic semiconductor materials to NIR light, one strategy is to use rare-earth (RE) ions doped up-conversion (UC) nanophosphors combined with the specific organic semiconductor film (e.g. poly(3-hexylthiophene-2,5-diyl), P3HT film) with a strong absorption rate of visible lights. NaYF₄ is considered as one of the most efficient host for NIR-to-visible conversion due to its low phonon energy and multiple dopant. The key factor is the unique nonlinear UC optical process where high-energy photons are generated by absorbing two or more low-energy near-infrared photons. The resultant high-energy visible emissions are subsequently efficiently absorbed by the organic semiconductor film.

Although, a composite P3HT semiconductor polymer film with NaYF₄:Yb,Er UC nanoparticles was recently reported to have a response to NIR light, the reported photocurrent enhancement was insignificant and hardly useful for device design and fabrication.

Accordingly, there remains a need to provide for an improved photoconductive nanocomposite film useful for optoelectronic device and fabrication.

### SUMMARY

According to a first aspect of the invention, there is provided a solvothermal decomposition method for forming lanthanide-doped hexagonal sodium yttrium fluoride (NaYF₄) core-shell nanoparticles.

The solvothermal decomposition method includes dissolving in an organic solution (i) a mixture of lanthanide trifluoroacetates and sodium trifluoroacetate, wherein the mixture of lanthanide trifluoroacetates comprises yttrium trifluoroacetate and two other lanthanide trifluoroacetates, or (ii) a mixture of lanthanide-based organic salts with ammonium fluoride (NH₄F) or sodium fluoride (NaF), wherein the mixture of lanthanide-based organic salts comprises yttrium organic salts and two other lanthanide organic salts. In various embodiments, the lanthanide-based organic salts may be lanthanide trifluoroacetates, lanthanide acetylacetonates, lanthanide acetates, lanthanide oleates or lanthanide stearates.

The solvothermal decomposition method further includes heating the organic solution in an inert environment to obtain lanthanide-doped NaYF₄ nanoparticles.

The solvothermal decomposition method further includes adding a solution comprising yttrium trifluoroacetate and sodium trifluoroacetate to the lanthanide-doped NaYF₄ nanoparticles and heating the solution, thereby forming a shell layer encapsulating the lanthanide-doped NaYF₄ nanoparticles to obtain the lanthanide-doped NaYF₄ core-shell nanoparticles.

According to a second aspect of the invention, there is provided a method for forming an optoelectronic device.

The forming method includes coating a nanocomposite film on a substrate, wherein the nanocomposite film comprises lanthanide-doped hexagonal sodium yttrium fluoride (NaYF₄) nanoparticles formed by the solvothermal decomposition method of the first aspect dispersed in a semiconducting polymer.

The forming method further includes annealing the nanocomposite film and the substrate.

According to a third aspect of the invention, there is provided an optoelectronic device.

The optoelectronic device includes a nanocomposite film coated on a substrate, wherein the nanocomposite film comprises lanthanide-doped hexagonal sodium yttrium fluoride (NaYF₄) nanoparticles dispersed in a semiconducting polymer.

According to a fourth aspect, a light converting layer is disclosed herein. The light converting layer comprises lanthanide-doped hexagonal sodium yttrium fluoride (NaYF₄) nanoparticles formed by a method of the first aspect dispersed in a semiconducting polymer.

The light converting layer can convert low photon energy light to high photon energy emission that matches the absorption range of an organic or inorganic photodetector. With this combination, the detection range of the photodetector (e.g. Si photodetector) can be extended to the NIR range with enhanced photoresponsivity.

In one disclosed embodiment, the successful fabrication of a photoconductive composite film of poly(3-hexylthiophene-2,5-diyl) (P3HT) mixed with NaYF₄:Yb,Er nanophosphors that exhibited a ultrahigh photoresponse to infrared radiation is demonstrated. The high photocurrent measured was enabled by the unique up-conversion properties of NaYF₄:Yb,Er nanophosphors, where low photon energy infrared excitations (800-2000 nm) are converted to high photon energy emissions (200-1000 nm) that are later absorbed by P3HT. A significant 1.10×10⁵ time increment of photocurrent from the present photoconductive composite film upon infrared light exposure, which indicates high optical-to-electrical conversion efficiency, is achieved. Present disclosure therefore lays the groundwork for the future development of printable, portable, flexible and functional photonic composites for light sensing and harvesting, photonic memory devices, and phototransistors.

### BRIEF DESCRIPTION OF THE DRAWINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

FIG. 1 shows characterization of presently as-synthesized NaYF₄:Yb,Er core-shell nanoparticles. (a) TEM micrograph. Scale bar, 20 nm, (b) XRD profile, (c) Steady state emission spectrum, and (d) Time-resolved luminescence spectrum of the present up-conversion nanophosphors (UCNs).

FIG. 2 shows (a) Photoluminescence spectrum of UCN-P3HT nanocomposite film. (b) Atomic force microscopy (AFM) image of the present UCN-P3HT nanocomposite film. Scale bar, 200 nm. (c) Schematic of electronic transitions in NaYF4:Yb,Er core-shell nanoparticles upon 975 nm excitation. (d) Photograph of nanocomposite film on a flexible polyethylene terephthalate (PET) substrate.

FIG. 3 shows a photoconductor with the UCN-P3HT nanocomposite film. The thickness of each layer is not drawn to scale. (a) Schematic of the present photoconductor device integrating the present UCN-P3HT nanocomposite film. (b) Top-view microscope image of the device after all fabrication steps.

FIG. 4 shows electrical characteristics of photoconductors formed using the UCN-P3HT nanocomposite film. (a) I-V curve of photoconductor under illumination of a 975 nm laser pen. (b) and (c) Linear and log scale I-V curves of photocurrent under excitation of 975 nm laser with various power intensities. It shows a 1.1×10⁵ increment of photocurrent. (d) and (e) Linear and log scale I-V curves of photocurrent under excitation of 808 nm laser with various power intensities. It shows a 0.8×10⁵ increment of photocurrent. (f) Potential dependence of the increment of the photocurrent for 975 nm laser. (g) Potential dependence of the increment of the photocurrent for 808 nm laser.

FIG. 5 shows (a) SEM micrograph of NaYF₄:Yb,Er core-shell nanoparticles, Scale bar, 100 nm. (b) Size distribution of NaYF₄:Yb,Er core-shell nanoparticles.

FIG. 6 shows (a) EDX spectrum of NaYF₄:Yb,Er core-shell nanoparticles. (b) Table S1. Atomic percentage of each element of NaYF₄:Yb,Er core-shell nanoparticles calculated from EDX spectrum.

FIG. 7 shows photoluminescence spectra of NaYF₄:Yb,Er core and core-shell nanoparticles. The integrated intensity in green and red emission was increased by 27 and 100 times respectively after covering a NaYF₄ shell with the thickness of 2.9 nm.

FIG. 8 shows integrated intensity ratio of green to red emission of NaYF₄:Yb,Er core-shell nanoparticles and nanocomposite film.

FIG. 9 shows SEM image of nanocomposite film. Scale bar 1 μm.

FIG. 10 shows an image of flexible device using P3HT with NaYF₄:Yb,Er on polyethylene.

FIG. 11 shows electrical characteristics of the flexible device under 975 nm laser illumination. The 975 nm laser intensities are 0 W/cm², 0.1 W/cm², 1.8 W/cm², 4.1 W/cm², 6.7 W/cm², and 8.6 W/cm², respectively. High photocurrent achieved with a responsivity of 0.62 A/W at 2 V.

FIG. 12 shows two types of photodetector device structure: vertical-type and lateral-type wherein in both structures, the presently disclosed light converting layer comprising lanthanide-doped hexagonal sodium yttrium fluoride (NaYF₄) nanoparticles dispersed in a semiconducting polymer is used as the active layer.

### DESCRIPTION

The following detailed description refers to the accompanying drawings that show, by way of illustration, specific details and embodiments in which the invention may be practised. These embodiments are described in sufficient detail to enable those skilled in the art to practise the invention. Other embodiments may be utilized and structural, logical, chemical and electrical changes may be made without departing from the scope of the invention. The various embodiments are not necessarily mutually exclusive, as some embodiments can be combined with one or more other embodiments to form new embodiments.

Various embodiments relate generally to a method for forming lanthanide-doped hexagonal sodium yttrium fluoride (NaYF₄) core-shell nanoparticles.

In particular, the method is a solvothermal decomposition method. A solvothermal process can be defined as a process in a closed reaction vessel inducing decomposition or a chemical reaction between precursors in the presence of a solvent at a temperature higher than the decomposition temperature of the precursors.

The method involves dissolving a mixture of lanthanide trifluoroacetates and sodium trifluoroacetate in an organic solution, wherein the mixture of lanthanide trifluoroacetates comprises yttrium trifluoroacetate and two other lanthanide trifluoroacetates, followed by heating the organic solution in an inert environment to obtain the lanthanide-doped NaYF₄ nanoparticles.

Alternatively, the method involves dissolving a mixture of lanthanide-based organic salts with ammonium fluoride (NH₄F) or sodium fluoride (NaF), wherein the mixture of lanthanide-based organic salts comprises yttrium organic salts and two other lanthanide-based organic salts, followed by heating the organic solution in an inert environment to obtain the lanthanide-doped NaYF₄ nanoparticles. In various embodiments, the lanthanide-based organic salts may be lanthanide trifluoroacetates, lanthanide acetylacetonates, lanthanide acetates, lanthanide oleates or lanthanide stearates.

In various embodiments, the lanthanide dopants may be ytterbium (Yb), erbium (Er), or thulium (Tm). The corresponding trifluoroacetates are thus (CF₃COO)₃Yb, (CF₃COO)₃Er, and (CF₃COO)₃Tm. Other lanthanide dopants are also suitable, such as praseodymium, neodymium, samarium, europium, terbium, dysprosium, or holmium.

The amount and type of respective lanthanide trifluoroacetate to be dissolved may be varied, depending on the desired absorption and emission wavelengths. The wavelength selection will depend on the optical absorption behaviour of the organic photoconductor (e.g. P3HT) and preferred detection wavelength. In certain embodiments, the mixture of lanthanide trifluoroacetates and sodium trifluoroacetate may include 0.5 to 0.85 (such as 0.78) mmol of (CF₃COO)₃Y, 0.1 to 0.25 (such as 0.20) mmol of (CF₃COO)₃Yb, 0.01 to 0.05 (such as 0.02) mmol of (CF₃COO)₃Er and 1.0 to 2.0 (such as 1.5) mmol of CF₃COONa.

The mixture of lanthanide trifluoroacetates and sodium trifluoroacetate may be dissolved in an organic solution including a mixture of 1-octdecene, oleic acid, and oleylamine. In certain embodiments, the organic solution may include 3.0 to 4.0 (such as 3.2) mL of 1-octadecene, 2.0 to 3.0 (such as 2.5) mL of oleic acid and 1.5 to 2.5 (such as 2) mL of oleylamine.

The mixture is contained, and therefore the dissolution, is carried out in an enclosed surrounding such as a flask. The dissolution can be carried out in a flask at, say 120° C. or so under argon flow. After dissolving the lanthanide trifluoroacetates and sodium trifluoroacetate in the organic solvent, the resultant solution is heated to, say 300 to 340° C. or so and maintained at this temperature for a period of time (say 1 to 2 hours) in the argon environment under vigorous stirring to allow formation of the lanthanide-doped NaYF₄ nanoparticles.

To enhance the up-conversion efficiency, the lanthanide-doped NaYF₄ nanoparticles are coated with a shell layer encapsulating the lanthanide-doped NaYF₄ nanoparticles therein. The shell layer can be NaYF₄, NaNdF₄, NaGdF₄, NaYbF₄, NaTmF₄, NaDyF₄, NaLaF₄, NaTbF₄, NaLuF₄, NaSmF₄ and NaPrF₄. The thickness of shell layer is at least 1.5 nm. In other words, present method may be extended to include the formation of a core-shell structured lanthanide-doped NaYF₄ nanoparticles.

In certain embodiments, a solution for forming the shell layer may include (CF₃COO)₃Y, CF₃COONa, oleic acid and oleylamine. For example, the solution may include 0.5 to 1.5 (such as 1.0) mmol of (CF₃COO)₃Y, 1.0 to 2.0 (such as 1.5) mmol of CF₃COONa, 2.5 to 3.5 (such as 3.0) mL of oleic acid and 1.5 to 2.5 (such as 2.0) mL of oleylamine.

Sufficient time is allowed for the formation of the shell and after cooling, the synthesized core-shell nanoparticles can be separated and washed in ethanol by centrifugation, for example. Other washing techniques may also be used.

The thus-formed core-shell lanthanide-doped NaYF₄ nanoparticles may find use in optoelectronic devices, including but not limiting to photoconductors and photodetectors.

Accordingly, in various embodiments a method for forming an optoelectronic device is disclosed. The method includes coating a nanocomposite film on a substrate, wherein the nanocomposite film comprises lanthanide-doped hexagonal sodium yttrium fluoride (NaYF₄) nanoparticles formed by the method described above dispersed in a semiconducting polymer, followed by annealing the nanocomposite film and the substrate.

For optoelectronic devices requiring a rigid substrate, a silicon wafer may be used, for example. Typical substrate cleaning method may be used, such as cleaning the wafer with isopropanol and deionized water for a few mins and dried with nitrogen gas before use. Alternatively, germanium wafer or III-V materials wafer such as GaAs and InGaAs may be used as the rigid substrate.

Alternatively, a flexible substrate including plastics such as polyethylene terephthalate (PET), polyethylene naphthalate (PEN), graphene, graphene oxide, paper, or flexible glass may be used for applications such as wearable and portable optoelectronic devices.

The semiconductor polymer in which the lanthanide-doped NaYF₄ nanoparticles (whether of core-shell structure or not) are dispersed may be poly(3-hexylthiophene-2,5-diyl) (P3HT), phenyl-C61-butyric acid methyl ester (PCBM), P3HT:PCBM blend, poly[N-9-heptadecanyl-2,7-carbazole-alt-5,5-(4′,7′-di-2-thienyl-2′,1′,3′-benzothiadiazole)](PCDTBT), PCDTBT:PCBM blend, poly({4,8-bis[2-ethylhexyloxy]benzo[1,2-b:4,5-b′]dithiophene-2,6-diyl}(PTB7), PTB7:PCBM blend, P3HT:PTB7:PCBM blend, poly(9-vinylcarbazole) (PVK), and P3HT:PVK blend. The polymer semiconductor is a kind of materials that can absorb visible emission to generate electron-hole pairs. The nanocomposite film may be formed by spin-coating or solvent casting the solution containing the semiconductor polymer having the lanthanide-doped NaYF₄ nanoparticles dispersed therein.

The nanocomposite film may be coated on the substrate by spin-coating at a spinning rate of 2,000 to 8,000 (such as 6,000) rpm for a short period of time, say 60 s. This is followed by annealing at temperature of between 100 and 140° C., say 120° C., for a few minutes. Alternatively, the nanocomposite film may be coated onto the substrate, using printing, casting or other traditional coating methods.

After the coating of the nanocomposite film on the substrate, conductive contacts may be formed on the nanocomposite. For example, the conductive contacts can be metallic or otherwise. For metallic contacts, tantalum may be used, for example. For non-metallic contacts, graphene or transparent conductive oxide such as indium tin oxide may be used, for example.

The conductive contacts may be arranged on the nanocomposite by any known semiconductor processing techniques. For example, in the case of metallic contacts, lithographic technique may be used.

The device structure of the as-fabricated photodetector includes, but is not limited to, the lateral-type and vertical-type structures shown in FIG. 12. In the illustrated photodetector structures, the presently disclosed light converting layer comprising lanthanide-doped hexagonal sodium yttrium fluoride (NaYF₄) nanoparticles dispersed in a semiconducting polymer is used as the active layer. In the lateral-type structure (i.e. current flow is in the lateral direction), the active layer is coated on a substrate (e.g. silicon or any other flexible material). Conductive contacts, such as metals, are arranged on the active layer. In the vertical-type structure (i.e. current flow is in the vertical direction), the active layer is sandwiched between a first conductive layer on a first major side and a second conductive layer on a second major side of the active layer. The sandwich structure is then coated on a substrate (e.g. silicon or any other flexible material). Preferably, at least one of the conductive layers is transparent.

According to a fourth aspect, a light converting layer is disclosed herein. The light converting layer comprises lanthanide-doped hexagonal sodium yttrium fluoride (NaYF₄) nanoparticles formed by a method of the first aspect dispersed in a semiconducting polymer.

The light converting layer can convert low photon energy light to high photon energy emission that matches the absorption range of an organic or inorganic photodetector. With this combination, the detection range of the photodetector (e.g. Si photodetector) can be extended to the NIR range with enhanced photoresponsivity.

In order that the invention may be readily understood and put into practical effect, particular embodiments will now be described by way of the following non-limiting examples.

### EXAMPLES

In this example, the successful fabrication of the composite P3HT film mixed with NaYF₄:Yb,Er UC nanophosphors that exhibits a high conversion efficiency of near-infrared light to electrical signals is reported.

It is further demonstrated the integration and application of these P3HT-nanophosphor composite films as photoconductive devices. An incredible photocurrent enhancement of ˜5 orders is measured under the excitation of near-infrared light with various wavelengths, leading to significant advancements for future design and fabrication of optoelectronics devices. For the next generation of wearable and portable optoelectronics devices, these cost-effective and highly photoresponsive P3HT-nanophosphor composite films with excellent mechanical flexibility promises to be an outstanding candidate.

Methods

Materials. Regioregular poly(3-hexylthiophene-2,5-diyl) (P3HT), was purchased from Rieke Metals Inc. (Nebraska, USA). Sodium trifluoroacetate (98%), yttrium (III) oxide (99.99%), ytterbium (III) oxide (99.9%), erbium (III) oxide (99.9%), trifluoroacetic acid (99%), toluene (99.8%), 1-octadecene (90%), oleic acid (90%) and oleylamine (70%) were purchased from Sigma-Aldrich (Sigma-Aldrich, St. Louis, Mo.). Chloroform (99.99%) was purchased from Aik Moh Chemicals Inc. All chemicals were used as received without any further purification.

Synthesis of NaYF4:Yb,Er core-shell nanoscrystals. The NaYF₄:Yb,Er core-shell nanoparticles were synthesized by using a solvothermal decomposition method. The lanthanide trifluoroacetate precursors were prepared by dissolving stoichiometric ratios of lanthanide oxide powders in trifluoroacetic acid at 80° C. In a typical experiment, a mixture of 0.78 mmol (CF₃COO)₃Y, 0.20 mmol (CF₃COO)₃Yb, 0.02 mmol (CF₃COO)₃Er and 1.5 mmol CF₃COONa was dissolved in an organic solution containing 3.2 mL 1-octadecene, 2.5 mL oleic acid and 2 mL oleylamine in a 50 mL three-necks flask at 120° C. under Argon gas flow. The obtained solution was heated to 330° C. and kept at this temperature for 1 h in the argon environment under vigorous stirring. Next, a shell solution containing 1 mmol (CF₃COO)₃Y, 1.5 mmol CF₃COONa, 3 mL oleic acid and 2 mL oleylamine was added to enable the formation of core-shell particles. Upon completion of the reaction and after cooling, the synthesized nanoparticles were separated and washed three times in ethanol by centrifugation.

Device fabrication. For the photoconductors, the silicon wafer with 1000 nm SiO₂ was used as the substrate. The wafers were cleaned with isopropanol and deionized water for 2 mins and dried with nitrogen gas before use. P3HT solution (15 mg/mL) was prepared by dissolving P3HT in a mixed solvent of chloroform and toluene at a volume ratio of 1:1. Then NaYF4:Yb,Er core-shell nanoparticles were dispersed in the P3HT solution at a volume ratio of 10 vol % and the obtained nanocomposite solution was ultrasonicated before spin-coating. The nanocomposite solution was spin-coated onto the as-fabricated substrate with a spinning rate of 6000 rpm for 60 s, followed by annealing at 120° C. for ˜3 min. After coating of the nanocomposite film on the substrate, the photoresist was coated using the spin coater at 3000 rpm followed by a 90° C. baking using hot plate for 1 min. Lithography was done using a Karl SUSS MA-600 mask aligner with a UV lamp. Post-exposure baking was done at 120° C. for 1 min using hot plate. Development was conducted to form the exposed area or desired pattern of the photoresist. The chemical residue was removed using deionized water and the sample was dried using nitrogen gas. A 100-nm-thick tantalum was deposited using an AJA physical sputtering system followed by lift-off process using acetone in an ultrasonic machine. Eventually, the tantalum metal pads were formed on the nanoparticle film and electrical characteristics could be measured on the above mentioned photoconductor structure. The dimension of the metal pads is 100 μm×100 μm.

Characterization. X-ray powder diffraction (XRD) pattern was measured on a D8 Eco Advance powder diffractometer (Bruker AXS Inc., Madison, Wis.) using Cu Kα radiation with wavelength of 1.5418 Å. Electronic micrographs were taken on a field emission scanning electron microscopy (FESEM, JSM-7600F, JEOL Ltd., JP). Steady state luminescence spectra were measured upon excitation with a 975 nm continuous wave laser (CNI MDL-III-975, Changchun New Industries Optoelectronics Tech. Co. Ltd, China) using a FLS980 Fluorescence Spectrometer (Edinburgh Instruments Ltd., U.K.). To measure the time-resolved luminescence spectrum, the excitation source was modulated using an electronic pulse modulator to obtain excitation pulse at pulse duration of 30 μs with a repetition rate of 10 Hz. The laser powers of 975 nm continuous wave laser and 808 nm continuous wave laser (CNI MDL-H-808, Changchun New Industries Optoelectronics Tech. Co. Ltd, China) were measured using a laser energy meter (FieldMaxll-P, Coherent Inc.). The electrical characterization was performed using CascadeMicrotech Summit 11000 probe station and Keithley 4200-SCS Semiconductor characterization system.

Results

Preparation and Characterization of NaYF4:Yb,Er Core-Shell Nanophosphors

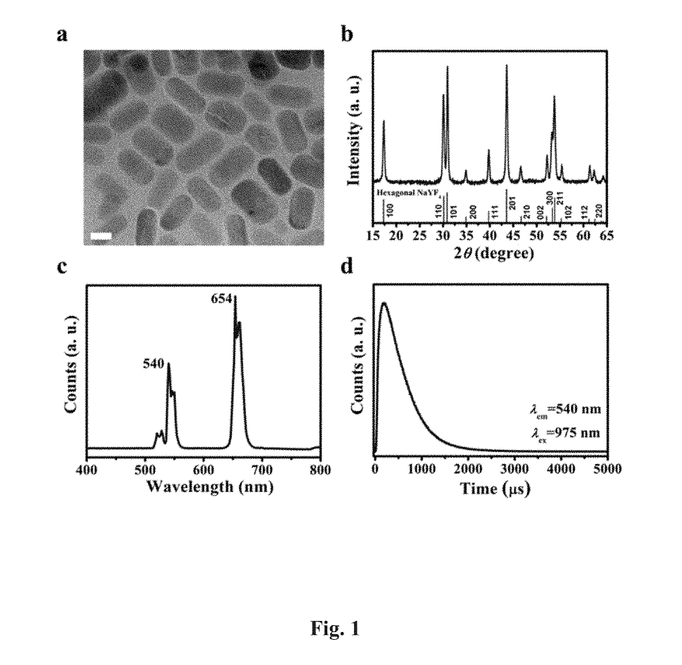

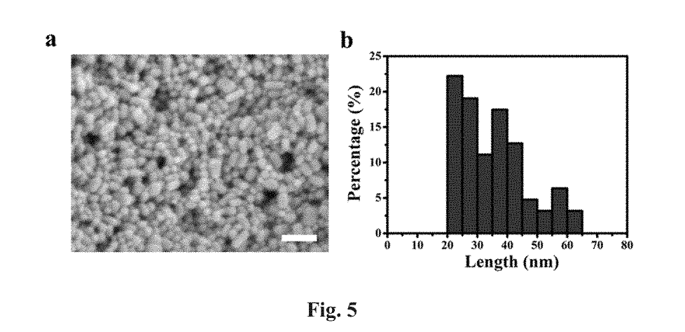

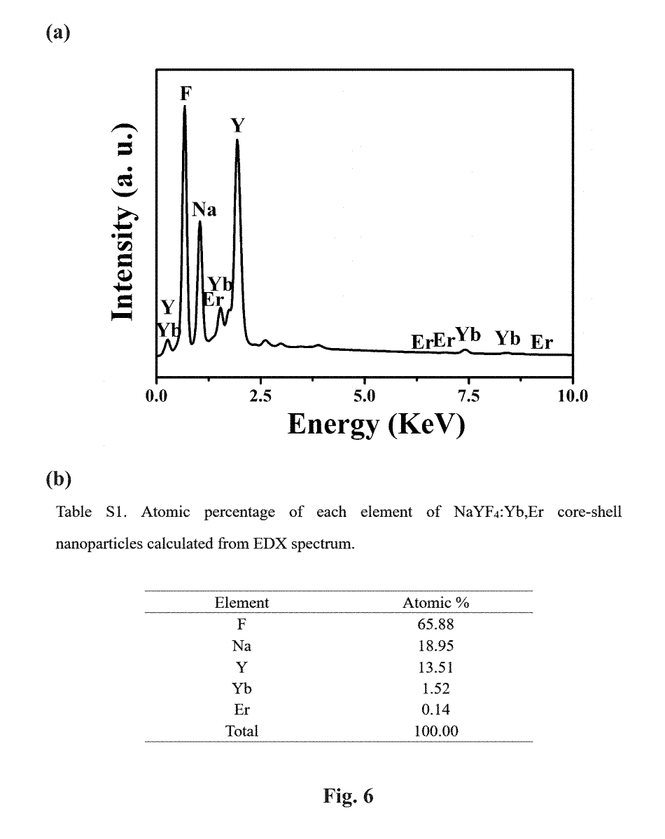

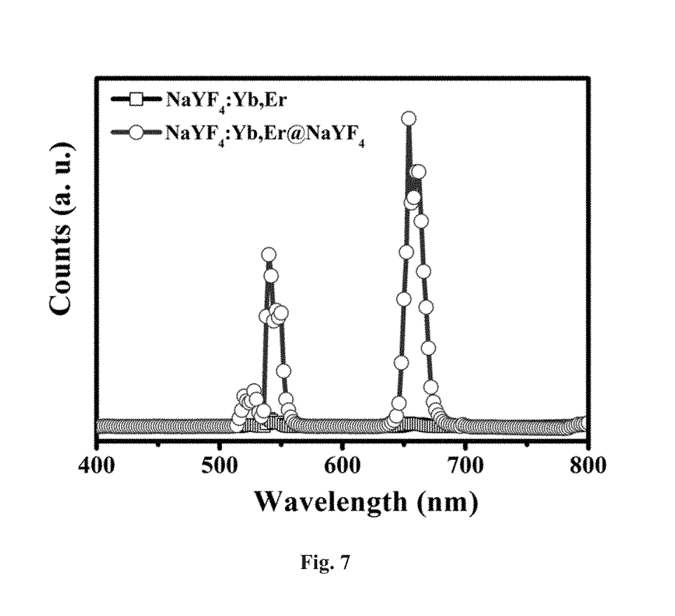

Hexagonal phase NaYF₄:Yb,Er core-shell up-conversion nanophosphors (UCN) with excellent visible up-conversion emissions upon excitation at 975 nm was synthesized using a thermal decomposition method (see FIG. 1). As shown in FIG. 1a, the NaYF₄:Yb,Er UCN is composed of mostly nanorods with a longitudinal size of 34.8±11.4 nm. The size distribution was measured from the SEM image of NaYF₄:Yb,Er UCN (FIG. 5a) and shown in FIG. 5b. The average aspect ratio (34.8 nm: 24.7 nm) of these nanoparticles is 1.4±0.4. The as-synthesized UCN consists of pure hexagonal NaYF₄ phase (JCPDS 16-0334) (FIG. 1b), where the broad XRD peaks indicate that small crystallites were synthesized. Using the Scherrer equation, the estimated grain size for the UCN was 25.6±1.8 nm. The EDX spectrum (FIGS. 6a and 6b) shows the existence of all the elements of Y, Yb, and Er which indicates that the RE ions were present in the present nanoparticles. It should be noted that due to the significant overlap of the L- and M-edges of Y, Yb, and Er, it was difficult to deconvolute the EDX spectrum peaks to reflect the concentrations of Y, Yb, and Er, especially considering the low Yb, Er dopant concentrations. Therefore, the measured Y compositions would also include contributions from the Yb and Er dopants. FIG. 1c shows the steady state emission spectrum of present UCNs upon excitation at 975 nm. The emission peaks are attributed to the ²H_{11/2→}⁴I^{15/2} (˜525 nm), ⁴S_{3/2→}⁴I_{15/2} (˜540 nm), ⁴F_{9/2→}⁴I_{15/2} (˜654 nm) transitions of the rare earth dopant, Er^{3±}. The undoped shell effectively eliminates any quenching that arises from surface defects or quenching groups (e.g., OH and CH₂ groups), and shields the Er³⁺0 emitting centers in the core from external contaminants and organic surfactants. Thus, the UC efficiency increased significantly upon coating the core with an undoped shell (see FIG. 7). FIG. 1d shows the time-resolved luminescence spectrum of our UCNs measured at 540 nm upon excitation at 975 nm. The luminescence decay curve was fitted using a single exponential equation of I=I₀ exp(−t/τ), where I₀ is the initial emission intensity at t=0 and τ is the fitted decay lifetime. The estimated decay time of as-synthesized UCNs was estimated to be ˜0.44 ms for the ⁴S_{3/2→}⁴I_{15/2} (˜540 nm) transition. The decay time characterizes the radiative and non-radiative relaxation of excited states. Generally a long decay time indicates low non-radiative losses and high emission efficiency. Thus, the long decay time of ˜0.44 ms for the presently disclosed UCNs compared to the reported value of ˜0.20 ms for a similar UCN with the same crystal (Wang et. al. J. Phys. Chem. C 2009, 113, 7164-7169) suggests that highly efficient UCNs using the presently disclosed synthesis method have been prepared.

Preparation and Characterization of Nanocomposite Film

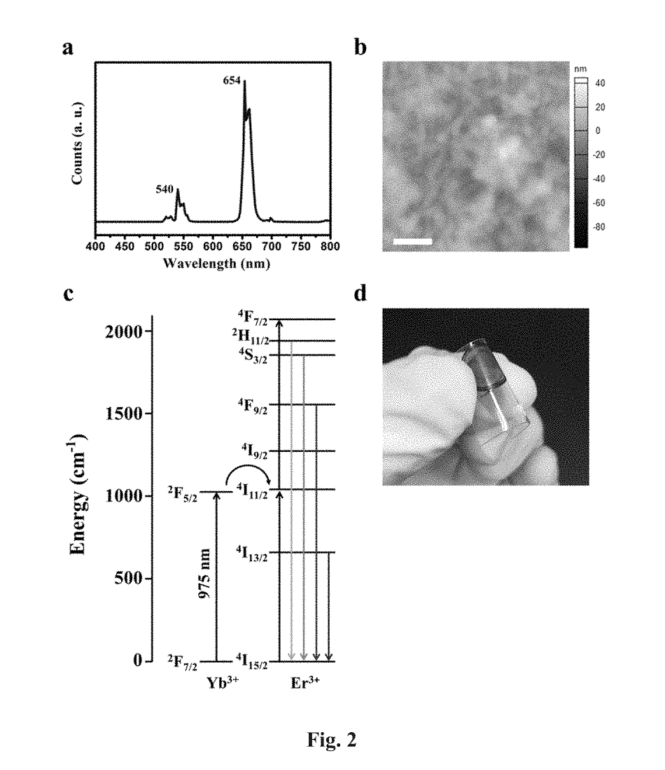

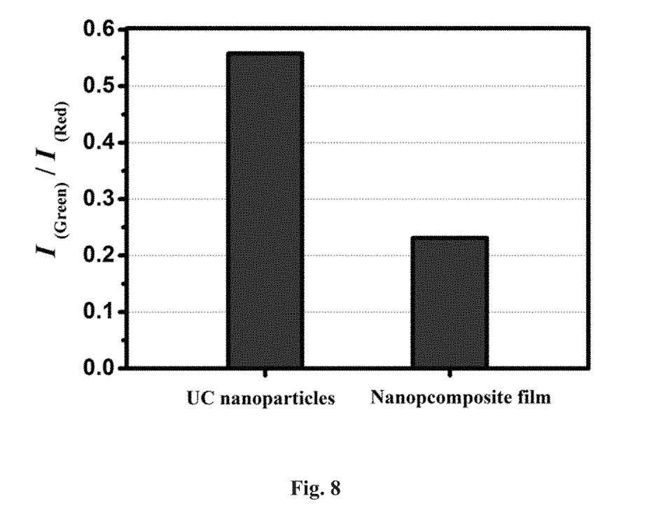

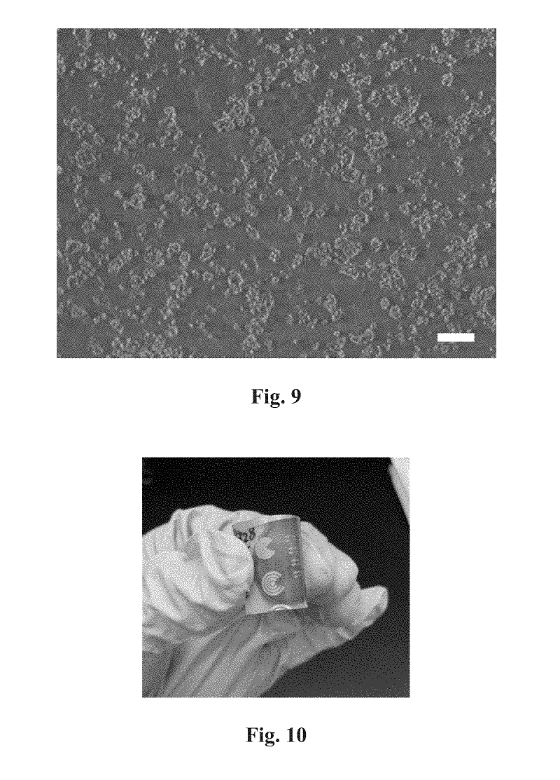

The nanocomposite film was fabricated by spin coating using a solution consisting of UCNs dispersed in a P3HT solution. The steady state emission spectrum of the present nanocomposite film is shown in FIG. 2a. The intensity of green emission at 540 nm decreases relative to that of red emission at 654 nm. The integrated intensity ratio of green to red emission of the present as-synthesized UCNs and nanocomposite film is shown in FIG. 8. The green-to-red ratio decreases from 0.56 for NaYF₄:Yb,Er core-shell nanoparticles to 0.23 for nanocomposite film. The observed decrease in green emission intensity is attributed to the preferred absorption of the green emission by P3HT. The surface of the obtained nanocomposite film was observed using both AFM (FIG. 2b) and SEM (FIG. 9). The root mean square (RMS) surface roughness is estimated to be ˜7.79 nm. The relatively small RMS value suggests that the surface is highly uniform. The uniform surface texture also indicates that the UCNs were homogenously dispersed within the P3HT film. The electronic transitions of the present UCNs is shown in FIG. 2c. Upon NIR excitation, the Yb³⁺ ions absorb NIR photons through the ²F_{7/2→}²I_{15/2} energy transition and subsequently undergo energy transfer to nearby Er³⁺ ions. Through energy transfer and cross-relaxation pathways, visible light is emitted through the ⁴S_{3/2→}⁴I_{15/2} (˜540 nm) and ⁴F_{9/2→}⁴I_{15/2} (˜654 nm) transitions of Er³⁺ ions. P3HT which has a bandgap of 1.9 eV results in corresponding absorption for wavelengths less than 650 nm. Thus, the visible emissions from the present UCNs are mostly absorbed by the P3HT molecules to generate electron-hole pairs or excitons. In this composite, the long excited-state lifetime of UCNs would be most beneficial to the exciton generation process. Photocurrent is generated when a voltage bias is applied to the nanocomposite film upon exposure to NIR light. With more excitons generated, a larger photocurrent would be expected. Therefore, the performance of the photoconductor under IR light is partly dictated by the UC efficiency of the present UCNs and the absorption efficiency of visible emission by the surrounding P3HT. To evaluate the possibility for making flexible device, P3HT film mixed with the present UCNs was spin coated on a polyethylene terephthalate (PET) substrate as shown in FIG. 2d. By visual inspection, it is observed that the present UCN-P3HT nanocomposite film adhered well with PET film and there is no visible breakage after multiple bending of the flexible substrate. The excellent adhesion demonstrates the outstanding potential of the present UCN-P3HT film for flexible device fabrication. An image of a flexible device is shown in FIG. 10.

Photoconductor Structure and Fabrication.

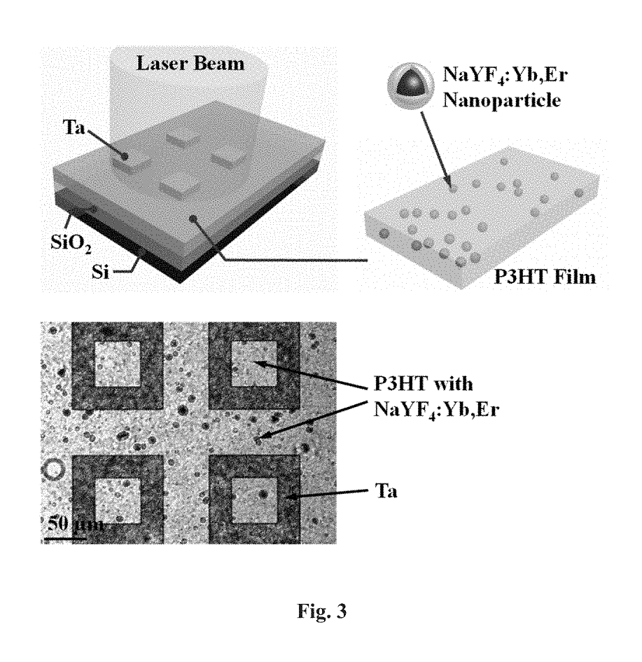

FIG. 3a shows the schematic illustration of a photoconductor incorporating the UCN-P3HT composite film which was fabricated using the conventional semiconductor technologies in this work. Silicon wafer with silicon dioxide (SiO₂) coated was used as the substrate material. After cleaning the top surface of SiO₂ using isopropanol (IPA) and deionized (DI) water, the P3HT composite film with the present UCNs was spin-coated onto the substrate followed by a 120° C. annealing for 3 minutes in air. The solution-based spin-coating process for the present UCN-P3HT composite film is much more cost-effective when compared to the fabrication of conventional III-V materials which needs an expensive and time consuming epitaxial growth process. Next, lithography, metal deposition, and lift-off steps were done to form the metal pads on top of the composite film. FIG. 3b shows the top-view image of the final device under an optical microscope. The whole process developed in this work shows a good compatibility to fabricate photoconductors with the present UCN-P3HT composite film using traditional semiconductor processes, indicating a possibility of seamlessly integrating the present UCN-P3HT composite film with the present semiconductor production line. Under excitation by near-infrared light, the NaYF₄:Yb,Er nanoparticles emit photons which are absorbed by P3HT polymer film, resulting in a photocurrent generated between two metal pads under an applied voltage bias. The intensity of the photocurrent depends on the photon-to-electrical conversion efficiency of the UCN-P3HT nanocomposite film.

Electrical Performance of the Photoconductor.

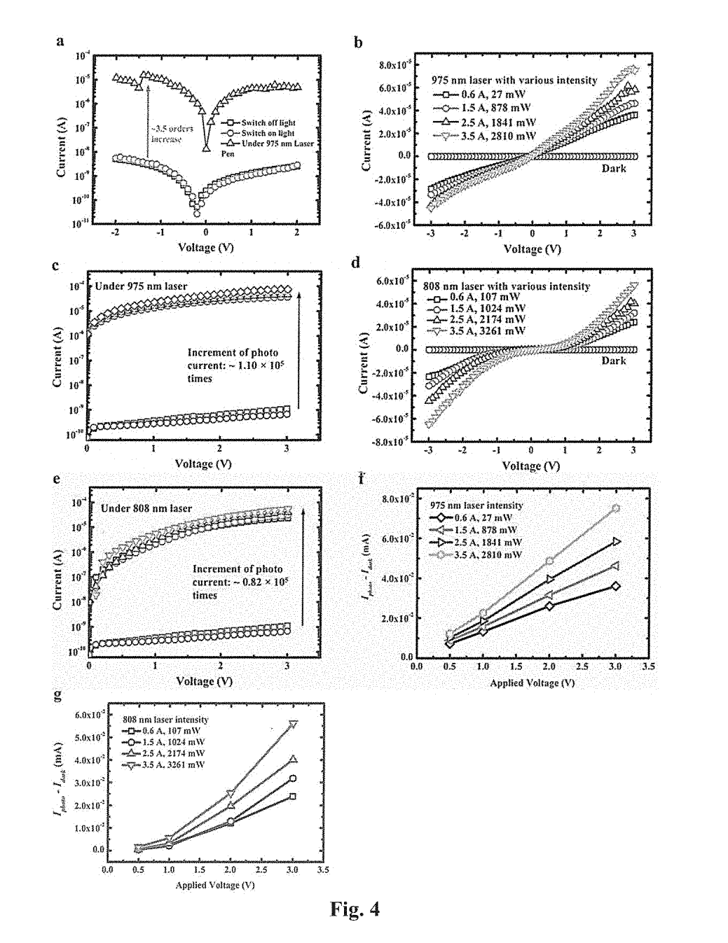

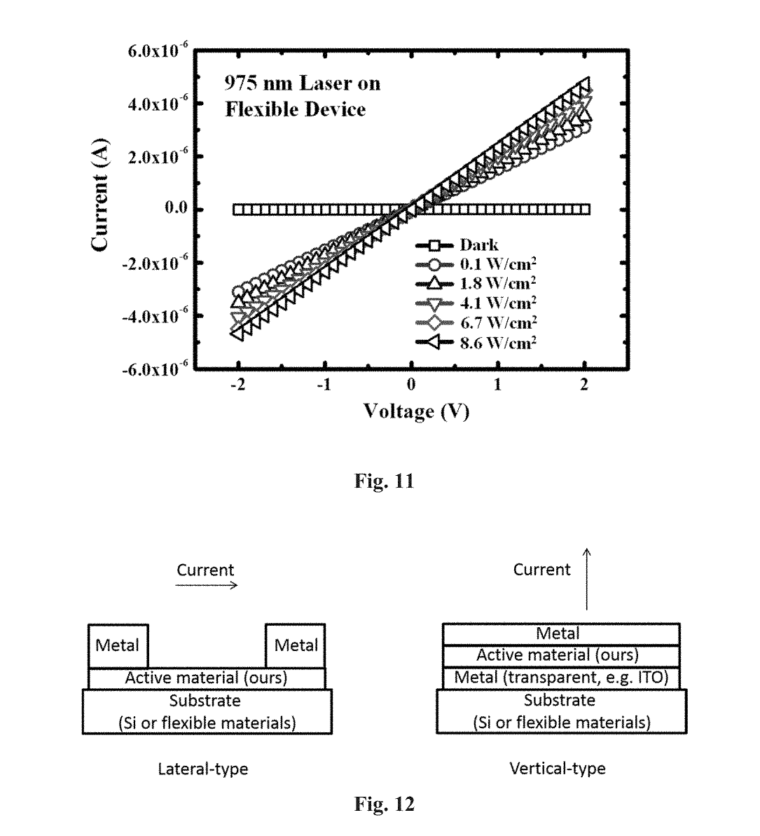

For the photoconductor fabricated using the composite film, we measured the electrical characteristics of the devices under the illumination of lasers at different wavelength. FIG. 4a shows the current-voltage (I-V) characteristics of the photoconductor under the illumination of a 975 nm wavelength laser pen. It is clearly observed that illumination at 975 nm leads to a considerable photocurrent increase of ˜3.5 orders when compared to dark current. The significant enhancement can be attributed to the enhanced absorption and conversion of the present UCN-P3HT nanocomposite film, where the efficiency of the UC emission processes of NaYF₄:Yb,Er nanophosphors was a critical determinant. The encouraging results that are obtained for the first-time for solution-processed photoconductions inspired further studies using excitation sources at other wavelengths (i.e. 975 nm and 808 nm) and power intensities using our photoconductors. In FIGS. 4b and 4c, it was found that the photocurrent increased with the increase of the 975 nm laser power. A significant ˜1.10×10⁵ times increment of photocurrent was achieved at the maximum illumination power (i.e. 2.81 W) using the 975 nm laser source. Compared to the results reported in the literature, this is a ˜2.75×10⁴ times enhancement in terms of the increment of the photocurrent under the illumination of laser (Zhou et al., Nat. Commun. 2014, 5, 4720). The large photocurrent increment further ascertains the compelling potential of using the nanocomposite film demonstrated in this work to advance the design of flexible optoelectronic devices. For measurements made using the 808 nm laser as shown in FIGS. 4d and 4e, an obvious ˜0.82×10⁵ times increment of photocurrent was found as well. The increment would be associated to the optical characteristics of the present UCNs, where NaYF₄:Yb,Er nanophosphors exhibit a response upon excitation at both 975 and 808 nm. It should be noted that it was found that the 975 nm laser source has a lower output power than that of the 808 nm laser source although the supplied current to the laser drivers is maintained at the same value, e.g. 3.5 A during the experiments. However, a higher photocurrent was measured upon illumination using the 975 nm laser than that of the 808 nm laser (at the same current). The higher photocurrent measured at 975 nm suggests that the present nanocomposite film was more responsive and sensitive to the 975 nm laser compared to that of the 808 nm laser. Next, the effect of potential difference on the increment of photocurrent (i.e. Iₚₕₒₜₒ-I_{dark}) was investigated for both 975 nm and 808 nm lasers as shown in FIGS. 4f and 4g. It was found that the increment of photocurrent became noticeably larger as the applied voltage on photoconductor increases. In addition, the saturation of photocurrent was not reached when the power intensity was at a maximum for both laser sources at 975 and 808 nm. Since photocurrent saturation has not been reached, the full potential of the present UCN-P3HT nanocomposite film as a photoconductor has not been realized and a further enhancement can be expected at higher laser powers. The electrical characteristics of flexible devices are shown in FIG. 11.

In summary, it has been successfully fabricated a highly sensitive photoconductor using the present UCN-P3HT nanocomposite film that was prepared using cost-effective solution-based processing method. In the present nanocomposite film, the energy of near-infrared lights is converted to photoelectrons by UC process. For the first time, a ˜5 orders increment of photocurrent was measured in this work upon near-infrared excitation. The photoconductor fabricated shows stronger photoresponse to 975 nm than that of the 808 nm laser source. The present approach and results demonstrated herein would lead the designs and fabrications for next generation flexible and wearable near-infrared optoelectronic devices. As such, possible applications of the present disclosure include all kinds of flexible electronic products for converting light-energy to electrical signal, e.g. flexible cost-effective photodetector, flexible and light-weight solar cell, flexible night vision devices, security, spectroscopy, and bioimaging.

By “comprising” it is meant including, but not limited to, whatever follows the word “comprising”. Thus, use of the term “comprising” indicates that the listed elements are required or mandatory, but that other elements are optional and may or may not be present.

By “consisting” it is meant including, and limited to, whatever follows the phrase “consisting of”. Thus, the phrase “consisting” indicates that the listed elements are required or mandatory, and that no other elements may be present.

The inventions illustratively described herein may suitably be practiced in the absence of any element or elements, limitation or limitations, not specifically disclosed herein. Thus, for example, the terms “comprising”, “including”, “containing”, etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the inventions embodied therein herein disclosed may be resorted to by those skilled in the art, and that such modifications and variations are considered to be within the scope of this invention.

By “about” in relation to a given numerical value, such as for temperature and period of time, it is meant to include numerical values within 10% of the specified value.

The invention has been described broadly and generically herein. Each of the narrower species and sub-generic groupings falling within the generic disclosure also form part of the invention. This includes the generic description of the invention with a proviso or negative limitation removing any subject matter from the genus, regardless of whether or not the excised material is specifically recited herein.

Other embodiments are within the following claims and non-limiting examples. In addition, where features or aspects of the invention are described in terms of Markush groups, those skilled in the art will recognize that the invention is also thereby described in terms of any individual member or subgroup of members of the Markush group.

1. A solvothermal decomposition method for forming lanthanide-doped hexagonal sodium yttrium fluoride (NaYF₄) core-shell nanoparticles, the method comprising:
dissolving in an organic solution (i) a mixture of lanthanide trifluoroacetates and sodium trifluoroacetate, wherein the mixture of lanthanide trifluoroacetates comprises yttrium trifluoroacetate and two other lanthanide trifluoroacetates, or (ii) a mixture of lanthanide-based organic salts with ammonium fluoride (NH₄F) or sodium fluoride (NaF), wherein the mixture of lanthanide-based organic salts comprises yttrium organic salts and two other lanthanide organic salts;
heating the organic solution in an inert environment to obtain lanthanide-doped NaYF₄ nanoparticles; and
adding a solution comprising yttrium trifluoroacetate and sodium trifluoroacetate to the lanthanide-doped NaYF₄ nanoparticles and heating the solution, thereby forming a shell layer encapsulating the lanthanide-doped NaYF₄ nanoparticles to obtain the lanthanide-doped hexagonal NaYF₄ core-shell nanoparticles.

2. The method of claim 1, wherein the lanthanide-based organic salts comprise lanthanide trifluoroacetates, lanthanide acetylacetonates, lanthanide acetates, lanthanide oleates or lanthanide stearates.

3. The method of claim 1, wherein the shell layer comprises NaYF₄, NaNdF₄, NaGdF₄, NaYbF₄, NaTmF₄, NaDyF₄, NaLaF₄, NaTbF₄, NaLuF₄, NaSmF4 or NaPrF₄.

4. The method of claim 1, wherein the shell layer has a thickness of at least 1.5 nm.

5. The method of claim 1, wherein the solution further comprises oleic acid, oleylamine, or a mixture thereof.

6. The method of claim 1, wherein the two other lanthanide trifluoroacetates in (i) are selected from the group consisting of ytterbium trifluoroacetate, erbium trifluoroacetate, praseodymium trifluoroacetate, neodymium trifluoroacetate, samarium trifluoroacetate, europium trifluoroacetate, terbium trifluoroacetate, dysprosium trifluoroacetate, holmium trifluoroacetate and thulium trifluoroacetate, or the two other lanthanide organic salts in (ii) are selected from the group consisting of ytterbium acetate, erbium acetate, praseodymium acetate, neodymium acetate, samarium acetate, europium acetate, terbium acetate, dysprosium acetate, holmium acetate and thulium acetate.

7. The method of claim 1, wherein the organic solution comprises 1-octadecene.

8. The method of claim 7, wherein the organic solution further comprises a coordinating ligand, wherein the coordinating ligand comprises oleic acid, oleylamine, or a mixture thereof.

9. (canceled)

10. The method of claim 1, further comprising dissolving one or more lanthanide oxides in trifluoroacetic acid to obtain one or more respective lanthanide trifluoroacetates used in the mixture of lanthanide trifluoroacetates.

11. A method for forming an optoelectronic device, the method comprising:
dissolving in an organic solution (i) a mixture of lanthanide trifluoroacetates and sodium trifluoroacetate, wherein the mixture of lanthanide trifluoroacetates comprises yttrium trifluoroacetate and two other lanthanide trifluoroacetates, or (ii) a mixture of lanthanide-based organic salts with ammonium fluoride (NH₄F) or sodium fluoride (NaF), wherein the mixture of lanthanide-based organic salts comprises yttrium organic salts and two other lanthanide organic salts;
heating the organic solution in an inert environment to obtain lanthanide-doped NaYF₄ nanoparticles;
adding a solution comprising yttrium trifluoroacetate and sodium trifluoroacetate to the lanthanide-doped NaYF₄ nanoparticles and heating the solution, thereby forming a shell layer encapsulating the lanthanide-doped NaYF₄ nanoparticles to obtain the lanthanide-doped hexagonal NaYF₄ core-shell nanoparticles;
dispersing the lanthanide-doped hexagonal NaYF₄ core-shell nanoparticles in a semiconducting polymer to form a nanocomposite film;
coating the nanocomposite film on a substrate, and
annealing the nanocomposite film and the substrate.

12. The method of claim 11, wherein dispersing the lanthanide-doped hexagonal NaYF₄ core-shell nanoparticles in the semiconductor polymer is by sonication.

13. The method of claim 11, wherein the coating comprises spin-coating, solvent casting or printing a nanocomposite solution comprising the lanthanide-doped hexagonal NaYF₄ core-shell nanoparticles dispersed in the semiconductor polymer.

14. The method of claim 11, further comprising forming conductive contacts on the nanocomposite film.

15. The method of claim 11, wherein the semiconducting polymer comprises poly(3-hexylthiophene-2,5-diyl) (P3HT), phenyl-C61-butyric acid methyl ester (PCBM), P3HT:PCBM blend, poly[N-9-heptadecanyl-2,7-carbazole-alt-5,5-(4′,7′-di-2-thienyl-2′,1′,3′-benzothiadiazole)](PCDTBT), PCDTBT:PCBM blend, poly({4,8-bis[2-ethylhexyloxy]benzo[1,2-b:4,5-Mdithiophene-2,6-diyl}(PTB7), PTB7:PCBM blend, P3HT:PTB7:PCBM blend, poly(9-vinylcarbazole) (PVK), or P3HT:PVK blend.

16. The method of claim 11, wherein the substrate is rigid, wherein the rigid substrate comprises a silicon wafer, a germanium wafer, a III-V materials wafer, or any combination thereof.

17. (canceled)

18. The method of claim 11, wherein the substrate is flexible.

19. The method of claim 18, wherein the flexible substrate is a plastic or the flexible substrate comprises polyethylene terephthalate (PET), polyethylene naphthalate (PEN), graphene, graphene oxide, paper, flexible glass, or any combination thereof.

20. (canceled)

21. The method of claim 11, wherein the optoelectronic device comprises a photoconductor or photodetector.

22. (canceled)

23. (canceled)

24. (canceled)

25. (canceled)

26. (canceled)

27. (canceled)

28. (canceled)

29. A light converting layer comprising lanthanide-doped hexagonal sodium yttrium fluoride (NaYF₄) core-shell nanoparticles dispersed in a semiconducting polymer.

30. The light converting layer of claim 29, wherein the semiconducting polymer comprises poly(3-hexylthiophene-2,5-diyl) (P3HT), phenyl-C61-butyric acid methyl ester (PCBM), P3HT:PCBM blend, poly[N-9-heptadecanyl-2,7-carbazole-alt-5,5-(4′,7′-di-2-thienyl-2′,1′,3′-benzothiadiazole)](PCDTBT), PCDTBT:PCBM blend, poly({4,8-bis[2-ethylhexyloxy]benzo[1,2-b:4,5-b′]dithiophene-2,6-diyl} (PTB7), PTB7:PCBM blend, P3HT:PTB7:PCBM blend, poly(9-vinylcarbazole) (PVK), or P3HT:PVK blend.
